(19) United States
(12) Patent Application Publication
(10) Pub. No.: US 2025/0324803 A1
(43) Pub. Date: Oct. 16, 2025

(54) SEMICONDUCTOR DEVICE, ELECTRONIC DEVICE, AND MANUFACTURING METHOD

(71) Applicant: SONY SEMICONDUCTOR SOLUTIONS CORPORATION, Kanagawa (JP)

(72) Inventor: Hitoshi OKANO, Kanagawa (JP)

(21) Appl. No.: 18/866,703

(22) PCT Filed: May 8, 2023
(86) PCT No.: PCT/JP2023/017235

§ 371 Date: Nov. 18, 2024

(30) Foreign Application Priority Data
May 27, 2022 (JP) 2022-087009

(51) Int. Cl. H10F 39/00; H01L 25/18; H10F 39/18; H10F 77/30

(52) U.S. Cl. CPC H10F 39/811; H01L 25/18; H10F 39/014; H10F 39/18; H10F 39/805; H10F 77/306

(57) ABSTRACT

The present disclosure relates to a semiconductor device, an electronic device, and a manufacturing method capable of reducing leakage and shrinking a keep out zone.

The semiconductor device includes a first semiconductor chip, a second semiconductor chip stacked on the first semiconductor chip and provided with a PN junction portion in a depth direction by forming an N-type well on a front surface of a substrate of P-type or forming a P-type well on a front surface of a substrate of N-type, and a through electrode provided in a through hole penetrating the substrate. The through electrode is configured such that a ferroelectric film or a thermal oxide film having an insulating property for at least the PN junction portion is provided along an inner wall surface of the through hole. The present technology can be applied to, for example, a stacked CMOS image sensor.

### TECHNICAL FIELD

The present disclosure relates to a semiconductor device, an electronic device, and a manufacturing method, and particularly to a semiconductor device, an electronic device, and a manufacturing method capable of reducing leakage and shrinking a keep out zone.

### BACKGROUND ART

In recent years, in various semiconductor devices, development of a three-dimensional stacking technology for achieving higher functionality by increasing a circuit scale mounted in one chip has been actively promoted. There has been developed, for example, a stacked complementary metal oxide semiconductor (CMOS) image sensor in which a sensor chip, a memory chip, and a logic chip are stacked by using a three-dimensional stacking technology such as bumps, through-silicon vias (TSVs), and Cu—Cu bonding. In addition, there have been proposed a wafer on wafer (WoW) structure in which a certain semiconductor wafer and another semiconductor wafer are bonded by using a TSV, a chip on wafer (CoW) structure in which a semiconductor wafer and a semiconductor chip are bonded by using a TSV, and the like.

In this manner, in a semiconductor device in which two or more layers are multilayered by using a three-dimensional stacking technology, since a front surface side and a back surface side of chips are connected, it is considered that a TSV penetrating the semiconductor substrate is used and a miniaturized TSV (n-TSV) is used.

In addition, in a normal semiconductor device, a front surface is covered with an N-type or P-type semiconductor (diffusion layer, well, or the like), and a PN junction is formed in a depth direction from the surface, such as a PN junction between the N-type diffusion layer and the P-type well or a PN junction between the P-type diffusion layer and the N-type well.

For example, as disclosed in Patent Document 1, in a case where a large number of miniaturized TSVs are used in a semiconductor device having a three-dimensionally stacked structure, designing is performed in a layout in which the miniaturized TSVs penetrate (longitudinally) a semiconductor substrate in which a PN junction is formed in the depth direction.

### CITATION LIST

### Patent Document

Patent Document 1: International Patent Publication No. 2019/087764

### SUMMARY OF THE INVENTION

### Problems to be Solved by the Invention

By the way, it is known that a defect occurs in a semiconductor substrate by plasma etching during processing of a TSV hole. Therefore, in a case where a depletion layer formed in the PN junction in the semiconductor substrate around the TSV is in contact with the TSV, a leakage current increases through a defect generated during processing. For example, such leakage can be reduced by providing a keep out zone (KoZ) that separates the TSV from the depletion layer due to the PN junction. However, in a case where a large number of miniaturized TSVs are used in the future and designing is performed in a layout in which chips are connected at an arbitrary position, it is necessary to consider that providing a keep out zone becomes a constraint. Therefore, it is required to reduce leakage and to shrink the keep out zone.

The present disclosure has been made in view of such a situation, and makes it possible to reduce leakage and shrink a keep out zone.

### Solutions to Problems

A semiconductor device according to one aspect of the present disclosure includes a first semiconductor chip, a second semiconductor chip stacked on the first semiconductor chip and provided with a PN junction portion in a depth direction by forming an N-type well on a front surface of a substrate of P-type or forming a P-type well on a front surface of a substrate of N-type, and a through electrode provided in a through hole penetrating the substrate, in which the through electrode is configured such that a first insulating film having an insulating property for at least the PN junction portion is provided along an inner wall surface of the through hole.

An electronic device according to one aspect of the present disclosure includes a semiconductor device including a first semiconductor chip, a second semiconductor chip stacked on the first semiconductor chip and provided with a PN junction portion in a depth direction by forming an N-type well on a front surface of a substrate of P-type or forming a P-type well on a front surface of a substrate of N-type, and a through electrode provided in a through hole penetrating the substrate, in which the through electrode is configured such that a first insulating film having an insulating property for at least the PN junction portion is provided along an inner wall surface of the through hole.

A method of manufacturing a semiconductor device according to one aspect of the present disclosure includes forming a through hole penetrating a substrate of a second semiconductor chip stacked on a first semiconductor chip and provided with a PN junction portion in a depth direction by forming an N-type well on a front surface of the P-type substrate or forming a P-type well on a front surface of the N-type substrate, and forming a through electrode having a configuration in which a first insulating film having an insulating property for at least the PN junction portion is provided along an inner wall surface of the through hole.

In one aspect of the present disclosure, a through hole and a through electrode are formed, the through hole penetrating a substrate of a second semiconductor chip stacked on a first semiconductor chip and provided with a PN junction portion in a depth direction by forming an N-type well on a front surface of the P-type substrate or forming a P-type well on a front surface of the N-type substrate, the through electrode having a configuration in which a first insulating film having an insulating property for at least the PN junction portion is provided along an inner wall surface of the through hole.

### BRIEF DESCRIPTION OF DRAWINGS

FIG. 1 is a diagram illustrating a configuration example of a first embodiment of a through electrode of a semiconductor device to which the present technology is applied.

FIG. 2 is a diagram for describing steps of forming the through electrode.

FIG. 3 is a diagram illustrating a modification of the through electrode.

FIG. 4 is a sectional view illustrating a first configuration example of the semiconductor device.

FIG. 5 is a sectional view illustrating a second configuration example of the semiconductor device.

FIG. 6 is a sectional view illustrating a third configuration example of the semiconductor device.

FIG. 7 is a sectional view illustrating a fourth configuration example of the semiconductor device.

FIG. 8 is a sectional view illustrating a fifth configuration example of the semiconductor device.

FIG. 9 is a sectional view illustrating a sixth configuration example of the semiconductor device.

FIG. 10 is a sectional view illustrating a seventh configuration example of the semiconductor device.

FIG. 11 is a sectional view illustrating an eighth configuration example of the semiconductor device.

FIG. 12 is a sectional view illustrating a ninth configuration example of the semiconductor device.

FIG. 13 is a view for illustrating a method of manufacturing the semiconductor device.

FIG. 14 is a view for illustrating the method of manufacturing the semiconductor device.

FIG. 15 is a view for illustrating the method of manufacturing the semiconductor device.

FIG. 16 is a diagram illustrating a configuration example of a second embodiment of the through electrode of the semiconductor device to which the present technology is applied.

FIG. 17 is a diagram for describing steps of forming the through electrode.

FIG. 18 is a diagram illustrating a modification of the through electrode.

FIG. 19 is a sectional view illustrating a tenth configuration example of the semiconductor device.

FIG. 20 is a sectional view illustrating an eleventh configuration example of the semiconductor device.

FIG. 21 is a sectional view illustrating a twelfth configuration example of the semiconductor device.

FIG. 22 is a sectional view illustrating a thirteenth configuration example of the semiconductor device.

FIG. 23 is a sectional view illustrating a fourteenth configuration example of the semiconductor device.

FIG. 24 is a sectional view illustrating a fifteenth configuration example of the semiconductor device.

FIG. 25 is a sectional view illustrating a sixteenth configuration example of the semiconductor device.

FIG. 26 is a sectional view illustrating a seventeenth configuration example of the semiconductor device.

FIG. 27 is a sectional view illustrating an eighteenth configuration example of the semiconductor device.

FIG. 28 is a view for illustrating a method of manufacturing the semiconductor device.

FIG. 29 is a view for illustrating the method of manufacturing the semiconductor device.

FIG. 30 is a view for illustrating the method of manufacturing the semiconductor device.

FIG. 31 is a view for illustrating the method of manufacturing the semiconductor device.

FIG. 32 is a block diagram illustrating a configuration example of an imaging device.

FIG. 33 is a diagram illustrating a use example in which an image sensor is used.

### MODE FOR CARRYING OUT THE INVENTION

Hereinafter, specific embodiments to which the present technology is applied will be described in detail with reference to the drawings.

### <First Configuration Example of Through Electrode>

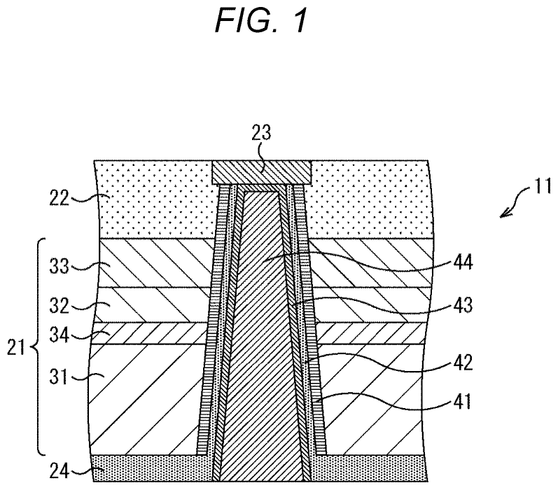

FIG. 1 is a diagram illustrating a configuration example according to a first embodiment of a through electrode used in a semiconductor device to which the present technology is applied.

As illustrated in FIG. 1, a through electrode 11 is provided so as to penetrate a semiconductor layer 21.

A wiring layer 22 is stacked on a front surface of the semiconductor layer 21, and a metal wire 23 is provided in the wiring layer 22. An insulating film 24 is stacked on a back surface of the semiconductor layer 21. The semiconductor layer 21 is configured such that a deep N-well layer 32 and an N-well layer 33 are formed on a P substrate 31, which is a P-type silicon substrate, so that a depletion layer 34 is provided at a PN junction portion where the P substrate 31 and the deep N-well layer 32 are bonded in a depth direction.

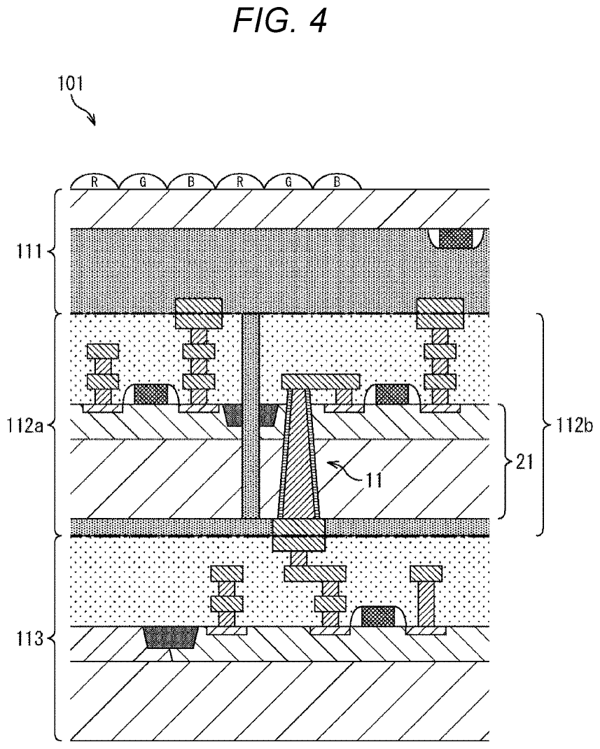

The through electrode 11 is formed by stacking a ferroelectric film 41, an insulating film 42, and a barrier metal 43 along an inner wall surface of a TSV hole formed so as to penetrate the semiconductor layer 21 from a back surface side of the semiconductor layer 21 to the wire 23, and further embedding a conductor 44. That is, the through electrode 11 penetrates the semiconductor layer 21, and is formed such that at least one end of the through electrode 11 is connected to the wire 23 constituting a part of an internal circuit (for example, a logic circuit of a logic chip 112 in FIG. 4) provided in the semiconductor device.

The ferroelectric film 41 is a structure including a ferroelectric and having a negative or positive fixed charge, is a film that spontaneously polarizes charging, and forms a hole accumulation layer. As illustrated in the drawing, the ferroelectric film 41 is stacked on an outside of the front surface of the semiconductor layer 21 on the inner wall surface of the TSV hole, and is provided with a length that covers at least the depletion layer 34 provided at the PN junction portion. For example, the ferroelectric film 41 includes BaTiO3 (barium titanate) which is a perovskite type oxide, Pb(Zr, Ti)O3, BiFeO3, SrBi2Ta2O9, (Bi, La)4Ti3O12, or the like. Alternatively, the ferroelectric film 41 can include High-k ferroelectric (for example, FE-HfO2, Zr, or the like). In addition, the ferroelectric film 41 is constituted by a single layer or a plurality of layers.

The insulating film 42 is stacked on the ferroelectric film 41, and is a film containing oxygen, such as a SiO2 film or a SiON film, for example. In addition, the insulating film 42 is formed simultaneously with the insulating film 24.

The barrier metal 43 is, for example, a metal film for preventing metal atoms constituting the conductor 44 from diffusing into the insulating film 42.

For the conductor 44, for example, metal such as copper is used.

The through electrode 11 is configured in this manner, and the ferroelectric film 41 has an insulating property for the depletion layer 34 provided at least in the PN junction portion, and it is therefore possible to reduce leakage in the depletion layer 34 caused by a defect generated during processing of the TSV hole. Furthermore, since the hole accumulation layer is formed by the ferroelectric film 41, the depletion layer 34 can be separated from a periphery of the through electrode 11, so that the keep out zone can be shrunk.

Therefore, by using the through electrode 11 having such a configuration in the semiconductor device, it is possible to achieve low power consumption with reduction of leakage. Furthermore, as a result of being able to shrink the keep out zone, for example, in a design using a large number of miniaturized through electrodes 11, it is possible to provide a layout in which chips are connected at arbitrary locations (for example, at a narrow pitch).

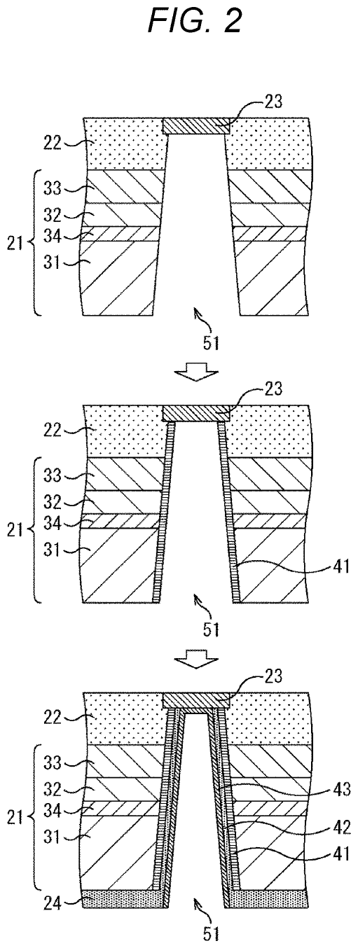

Steps of forming the through electrode 11 will be described with reference to FIG. 2.

First, as illustrated in a first part of FIG. 2, a TSV hole 51 penetrating the semiconductor layer 21 is formed so that the wire 23 opens from the back surface side of the semiconductor layer 21.

Next, as illustrated in a second part of FIG. 2, the ferroelectric film 41 is formed on the inner wall surface of the TSV hole 51.

Then, as illustrated in a third part of FIG. 2, the insulating film 42 is formed so as to be stacked on the ferroelectric film 41, and the insulating film 24 is formed on the back surface of the semiconductor layer 21. Furthermore, the barrier metal 43 is formed so as to be stacked on the insulating film 42 and the wire 23.

Thereafter, the conductor 44 is embedded in the TSV hole 51 to form the through electrode 11 as illustrated in FIG. 1.

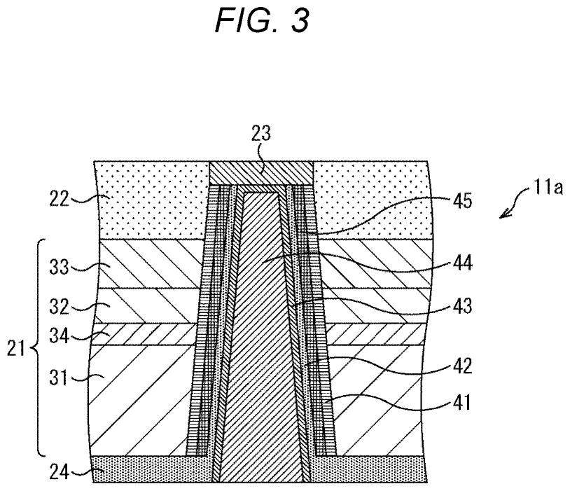

FIG. 3 is a diagram illustrating a modification of the through electrode 11.

A through electrode 11a illustrated in FIG. 3 is formed by stacking an insulating film 45 of a type different from the insulating film 42 between the ferroelectric film 41 and the insulating film 42. That is, the through electrode 11a has a configuration in which a two-layer film of the insulating film 42 and the insulating film 45 is formed. Of course, the through electrode 11 may adopt a configuration in which a multilayer film of two or more layers is formed.

### <Configuration Example of Semiconductor Device>

A semiconductor device using the through electrode 11 will be described with reference to FIGS. 4 to 12.

FIG. 4 is a sectional view illustrating a first configuration example of the semiconductor device.

FIG. 4 illustrates a semiconductor device 101 having a three-layer structure bonded at a bonding surface indicated by a one-dot chain line. The semiconductor device 101 has a three-layer structure in which a sensor chip 111 is disposed in a first layer, logic chips 112a and 112b are disposed in a second layer, and a logic chip 113 is disposed in a third layer, and has a configuration called a multi-chip. For example, the sensor chip 111 is an imaging element such as a CMOS image sensor, and the logic chips 112a and 112b and the logic chip 113 include a signal processing circuit (logic circuit, memory, or the like) for performing signal processing on an image captured by the sensor chip 111.

Then, the semiconductor device 101 is configured such that the through electrode 11 is provided so as to penetrate the semiconductor layer 21 of the logic chip 112b. Therefore, the semiconductor device 101 can reduce leakage in the depletion layer 34 of the PN junction portion and shrink the keep out zone as described with reference to FIG. 1.

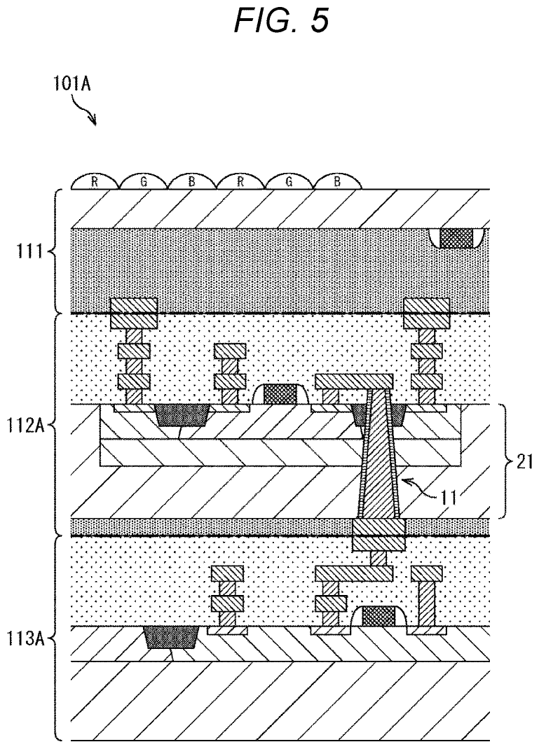

Note that, in each configuration example illustrated in FIGS. 5 to 12, the same reference sign is given to a configuration common to the configuration of the semiconductor device 101 in FIG. 4, and a detailed description thereof will be omitted.

FIG. 5 is a sectional view illustrating a second configuration example of the semiconductor device.

FIG. 5 illustrates a semiconductor device 101A having a three-layer structure bonded at a bonding surface indicated by a one-dot chain line. The semiconductor device 101A has a three-layer structure in which the sensor chip 111 is disposed in the first layer, a logic chip 112A is disposed in the second layer, and a logic chip 113A is disposed in the third layer, and has a configuration called F2F in which a front surface side of the sensor chip 111 and a front surface side of the logic chip 112A are bonded.

Then, the semiconductor device 101A is configured such that the through electrode 11 is provided so as to penetrate the semiconductor layer 21 of the logic chip 112A. Therefore, the semiconductor device 101A can reduce leakage in the depletion layer 34 of the PN junction portion and shrink the keep out zone as described with reference to FIG. 1.

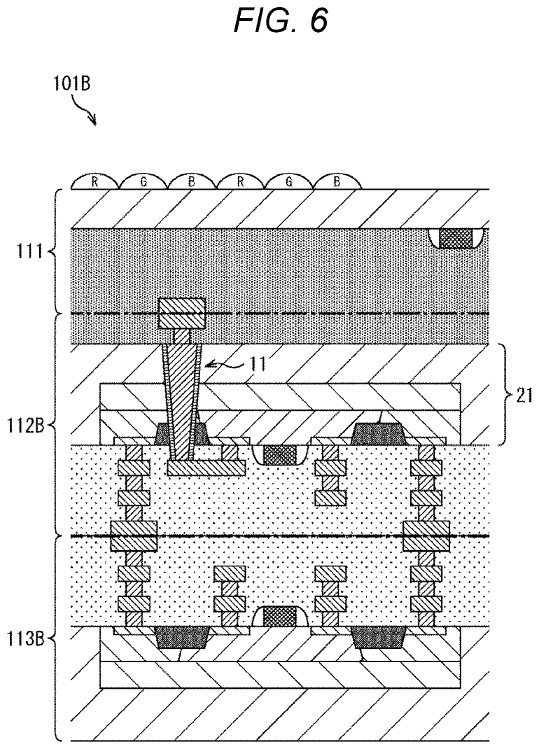

FIG. 6 is a sectional view illustrating a third configuration example of the semiconductor device.

FIG. 6 illustrates a semiconductor device 101B having a three-layer structure bonded at a bonding surface indicated by a one-dot chain line. The semiconductor device 101B has a three-layer structure in which the sensor chip 111 is disposed in the first layer, a logic chip 112B is disposed in the second layer, and a logic chip 113B is disposed in the third layer, and has a configuration called F2B in which a front surface side of the sensor chip 111 and a back surface side of the logic chip 112B are bonded.

Then, the semiconductor device 101B is provided with the through electrode 11 so as to penetrate the semiconductor layer 21 of the logic chip 112B. Therefore, the semiconductor device 101B can reduce leakage in the depletion layer 34 of the PN junction portion and shrink the keep out zone as described with reference to FIG. 1.

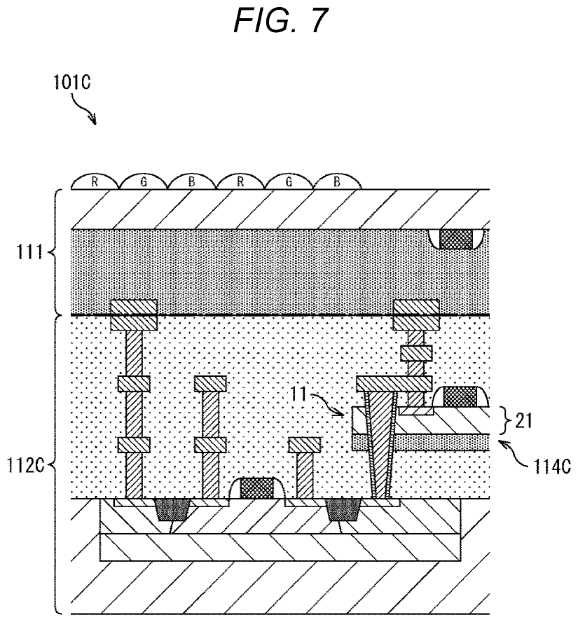

FIG. 7 is a sectional view illustrating a fourth configuration example of the semiconductor device.

FIG. 7 illustrates a semiconductor device 101C having a two-layer structure bonded at a bonding surface indicated by a one-dot chain line. The semiconductor device 101C has a two-layer structure in which the sensor chip 111 is disposed in the first layer and a logic chip 112C is disposed in the second layer, and has a configuration called monolithic in which the logic chip 112C is provided in a wiring layer of a logic chip 114C.

Then, the semiconductor device 101C is configured such that the through electrode 11 is provided so as to penetrate the semiconductor layer 21 of the logic chip 114C. Therefore, the semiconductor device 101C can reduce leakage in the depletion layer 34 of the PN junction portion and shrink the keep out zone as described with reference to FIG. 1.

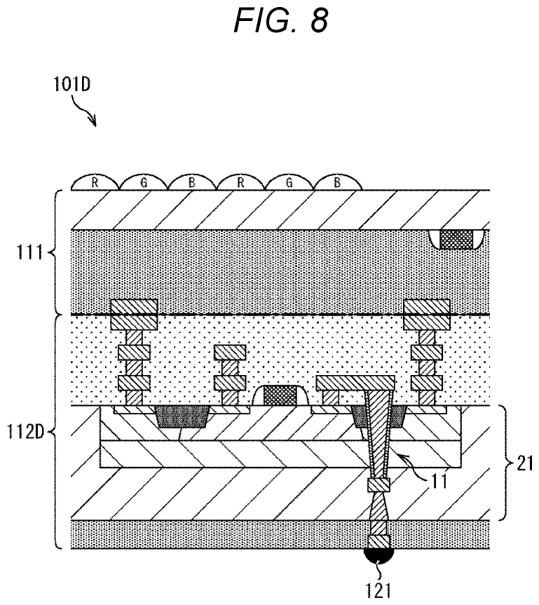

FIG. 8 is a sectional view illustrating a fifth configuration example of the semiconductor device.

FIG. 8 illustrates a semiconductor device 101D having a two-layer structure bonded at a bonding surface indicated by a one-dot chain line. The semiconductor device 101D has a two-layer structure in which the sensor chip 111 is disposed in the first layer and the logic chip 112D is disposed in the second layer, and has a configuration called a back surface bump in which a bump 121 is provided on a back surface side of the logic chip 112D.

Then, the semiconductor device 101D is configured such that the through electrode 11 is provided so as to be connected to the electrode connected to the bump 121 inside the semiconductor layer 21 of the logic chip 112D and penetrate at least the depletion layer 34 of the PN junction portion illustrated in FIG. 1. Therefore, the semiconductor device 101D can reduce leakage in the depletion layer 34 of the PN junction portion and shrink the keep out zone as described with reference to FIG. 1.

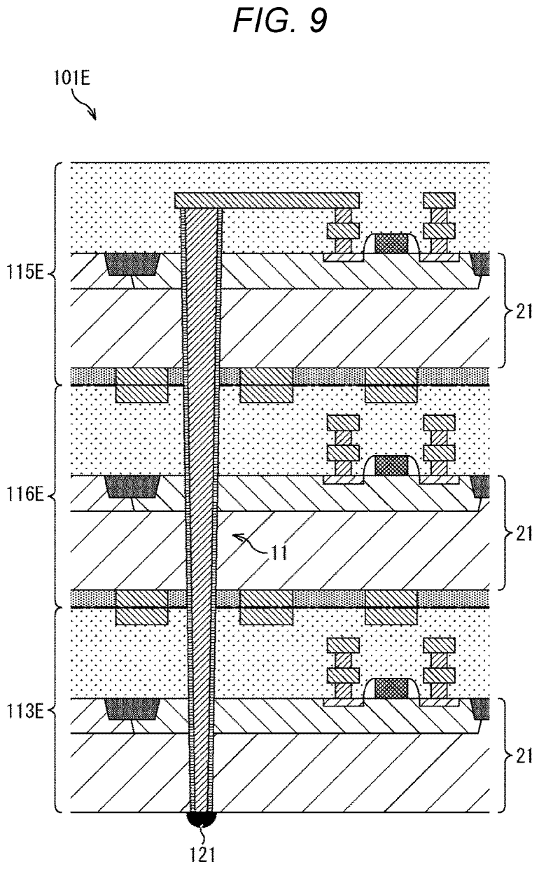

FIG. 9 is a sectional view illustrating a sixth configuration example of the semiconductor device.

FIG. 9 illustrates a semiconductor device 101E having a three-layer structure bonded at a bonding surface indicated by a one-dot chain line. The semiconductor device 101E has a three-layer structure in which a memory chip 115E is disposed in a first layer, a memory chip 116E is disposed in a second layer, and a logic chip 113E is disposed in a third layer, and has a configuration called a multistage memory/logic. Note that the semiconductor device 101E can be mounted on a support substrate (not illustrated) with the bump 121 provided on a back surface side of the logic chip 113E interposed therebetween. Of course, the semiconductor device 101E may have a layered structure of three or more layers.

Then, the semiconductor device 101E is configured such that the through electrode 11 is configured so as to pass through the semiconductor layer 21 of each of the memory chip 115E, the memory chip 116E, and the logic chip 113E to be connected to the bump 121. Therefore, the semiconductor device 101E can reduce leakage in the depletion layer 34 of the PN junction portion and shrink the keep out zone as described with reference to FIG. 1.

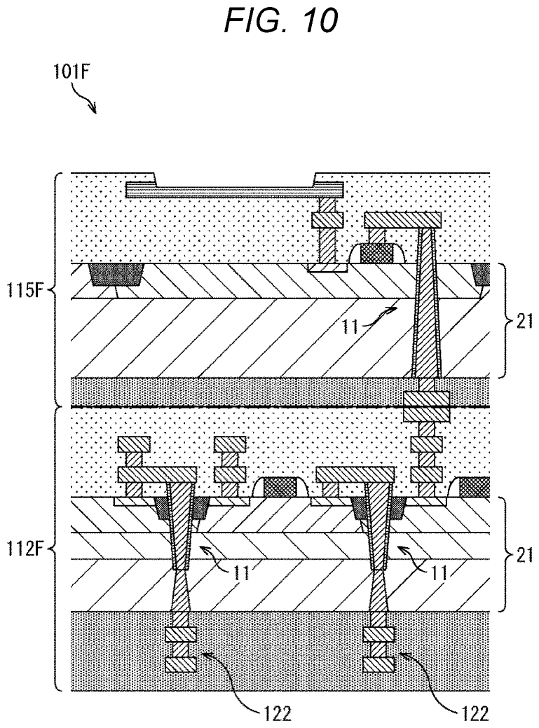

FIG. 10 is a sectional view illustrating a seventh configuration example of the semiconductor device.

FIG. 10 illustrates a semiconductor device 101F having a two-layer structure bonded at a bonding surface indicated by a one-dot chain line. The semiconductor device 101F has a two-layer structure in which the memory chip 115F is disposed in the first layer and a logic chip 112F is disposed in the second layer, and has a configuration in which the wire 122 for power supply is provided in a wiring layer of the logic chip 112F.

Then, the semiconductor device 101F is configured such that the through electrode 11 is provided so as to penetrate the semiconductor layer 21 of the memory chip 115F. In addition, the semiconductor device 101F is configured such that the through electrode 11 is provided so as to be connected to the electrode connected to the wire 122 inside the semiconductor layer 21 of the logic chip 112F and penetrate at least the depletion layer 34 of the PN junction portion illustrated in FIG. 1. Therefore, the semiconductor device 101F can reduce leakage in the depletion layer 34 of the PN junction portion and shrink the keep out zone as described with reference to FIG. 1.

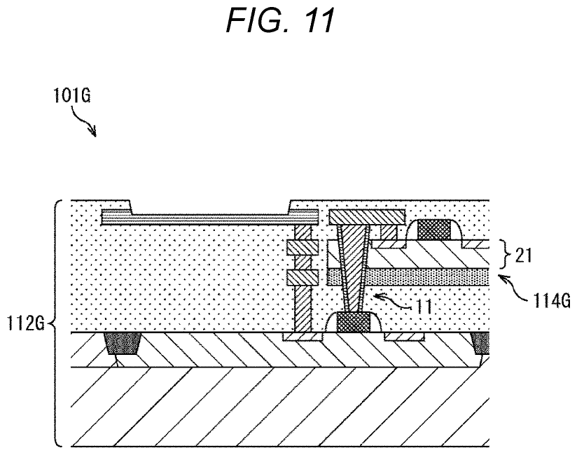

FIG. 11 is a sectional view illustrating an eighth configuration example of the semiconductor device.

FIG. 11 illustrates a semiconductor device 101G having a single layer structure. The semiconductor device 101G has a configuration called monolithic in which the logic chip 112G is provided in a wiring layer of the logic chip 114G.

Then, the semiconductor device 101G is configured such that the through electrode 11 is provided so as to penetrate the semiconductor layer 21 of the logic chip 114G. Therefore, the semiconductor device 101G can reduce leakage in the depletion layer 34 of the PN junction portion and shrink the keep out zone as described with reference to FIG. 1.

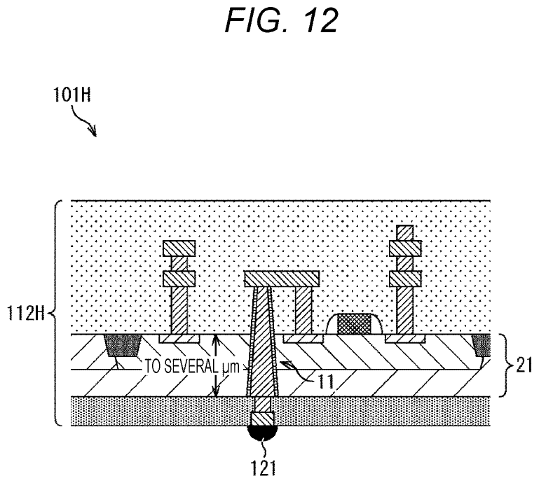

FIG. 12 is a sectional view illustrating a ninth configuration example of the semiconductor device.

FIG. 12 illustrates a semiconductor device 101H having a single layer structure. The semiconductor device 101H includes a logic chip 112H. Note that the semiconductor layer 21 of the logic chip 112H has a thickness of several μm or less.

Then, the semiconductor device 101H is configured such that the through electrode 11 is provided so as to penetrate the semiconductor layer 21 of the logic chip 112H, and the through electrode 11 is connected to the electrode connected to the bump 121. Therefore, the semiconductor device 101H can reduce leakage in the depletion layer 34 of the PN junction portion and shrink the keep out zone as described with reference to FIG. 1.

As described above, the through electrode 11 to which the present technology is applied can be applied to imaging element chips such as the semiconductor devices 101 to 101D, a signal processing chip such as the semiconductor devices 101E to 101H, and the like.

### <Method of Manufacturing Semiconductor Device>

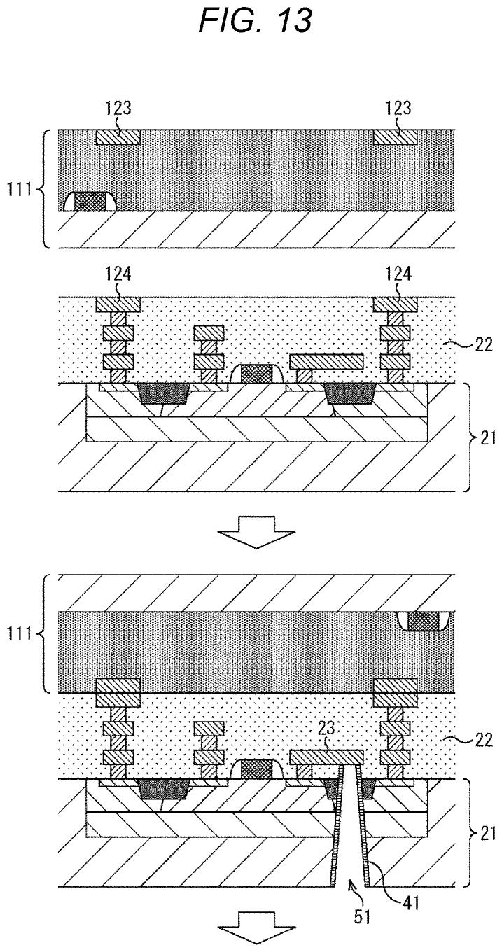

A method of manufacturing the semiconductor device 101A in FIG. 5 will be described with reference to FIGS. 13 to 15.

In a first step, as illustrated in an upper part of FIG. 13, the sensor chip 111 and the semiconductor layer 21 on which the wiring layer 22 is stacked are prepared by another process. Then, the layers are stacked by Cu—Cu bonding using a Cu pad 123 provided on the front surface side of the sensor chip 111 and a Cu pad 124 provided on a front surface side of the wiring layer 22.

In a second step, as illustrated in a lower part of FIG. 13, the TSV hole 51 penetrating the semiconductor layer 21 is formed so that the wire 23 opens from the back surface side of the semiconductor layer 21. Then, the ferroelectric film 41 is formed on the inner wall surface of the TSV hole 51.

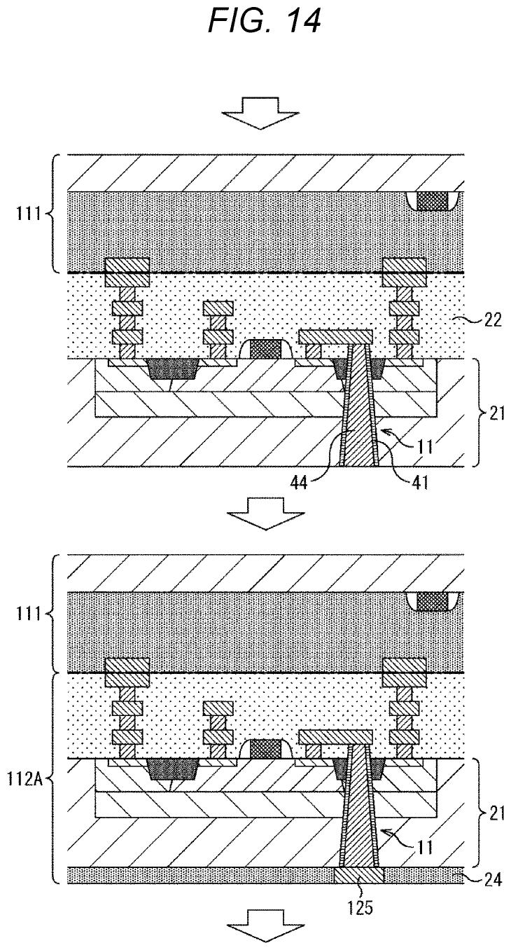

In a third step, as illustrated in an upper part of FIG. 14, the conductor 44 is embedded in the TSV hole 51 to form the through electrode 11. Note that, although not illustrated, the insulating film 42 and the barrier metal 43 are formed in the TSV hole 51 before the conductor 44 is embedded as described above with reference to FIG. 2.

In a fourth step, as illustrated in a lower stage of FIG. 14, the insulating film 24 is formed on the back surface of the semiconductor layer 21, and a Cu pad 125 is embedded in a part of the insulating film 24 so as to be connected to the through electrode 11. In this manner, the logic chip 112A is formed.

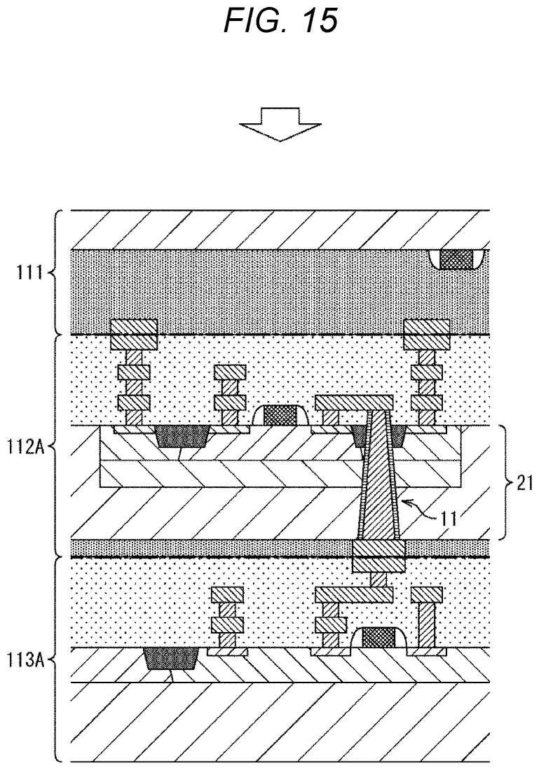

In a fifth step, as illustrated in FIG. 15, the logic chip 112A and the logic chip 113A prepared by another process are Cu—Cu bonded and stacked. Thereafter, a color filter, an on-chip lens, or the like is formed on a back surface side of the sensor chip 111 to manufacture the semiconductor device 101A as illustrated in FIG. 5.

The above steps makes it possible to manufacture the semiconductor device 101A having a three-layer structure in which the sensor chip 111, the logic chip 112A, and the logic chip 113A are stacked, and the logic chip 112A and the logic chip 113A are connected by using the through electrode 11.

### <Second Configuration Example of Through Electrode>

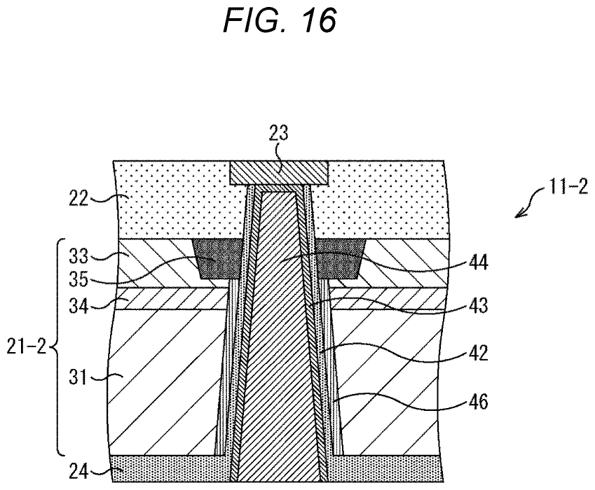

FIG. 16 is a diagram illustrating a configuration example according to a second embodiment of a through electrode used in a semiconductor device to which the present technology is applied. Note that, in a through electrode 11-2 illustrated in FIG. 16, a configuration common to the configuration of the through electrode 11 in FIG. 1 is denoted by the same reference sign, and a detailed description thereof will be omitted.

As illustrated in FIG. 16, a through electrode 11-2 is provided so as to penetrate a semiconductor layer 21-2.

The semiconductor layer 21-2 is configured such that the N-well layer 33 are formed on the P substrate 31, which is a P-type silicon substrate, so that the depletion layer 34 is provided at the PN junction portion where the P substrate 31 and the N-well layer 33 are bonded. In addition, an element isolator (shallow trench isolation (STI)) 35 for isolating elements is provided on a front surface of the semiconductor layer 21-2, and a through electrode 11-2 is provided so as to penetrate the element isolator 35.

The through electrode 11-2 has a configuration different from the configuration of the through electrode 11 in FIG. 1 in that a thermal oxide film 46 is formed inside a surface of an inner wall surface of the semiconductor layer 21-2 in a TSV hole formed so as to penetrate the semiconductor layer 21-2 from a back surface side of the semiconductor layer 21-2 to the wire 23. That is, while the through electrode 11 in FIG. 1 has a configuration in which the ferroelectric film 41 is stacked on the outside of the surface of the inner wall surface of the TSV hole, the through electrode 11-2 has a configuration in which the thermal oxide film 46 is formed inside the surface of the inner wall surface of the semiconductor layer 21-2 by performing a thermal oxidation treatment after forming the TSV hole.

Then, the through electrode 11-2 is formed by stacking the insulating film 42 and the barrier metal 43 on the outside of the surface of the inner wall surface of the TSV hole, and further embedding the conductor 44.

The thermal oxide film 46 is formed by, for example, changing silicon itself on the front surface of the semiconductor layer 21-2 into a silicon oxide film by oxidation by heating in the thermal oxidation treatment. In addition, the thermal oxide film 46 is provided only on a portion of the semiconductor layer 21-2 on the inner wall surface of the TSV hole, and is provided at a position deeper than the element isolator 35.

The through electrode 11-2 is configured in this manner, and the thermal oxide film 46 has an insulating property for the depletion layer 34 provided at least in the PN junction portion, and it is therefore possible to reduce leakage in the depletion layer 34 caused by a defect generated during processing of the TSV hole. Furthermore, the number of defects in the depletion layer 34 around the through electrode 11-2 can be reduced by the thermal oxide film 46, so that the keep out zone can be shrunk.

Therefore, by using the through electrode 11-2 having such a configuration in a semiconductor device, it is possible to achieve low power consumption with reduction of leakage, and to provide a layout in which chips are connected at an arbitrary position (for example, at a narrow pitch) in a design using a large number of miniaturized through electrodes 11-2.

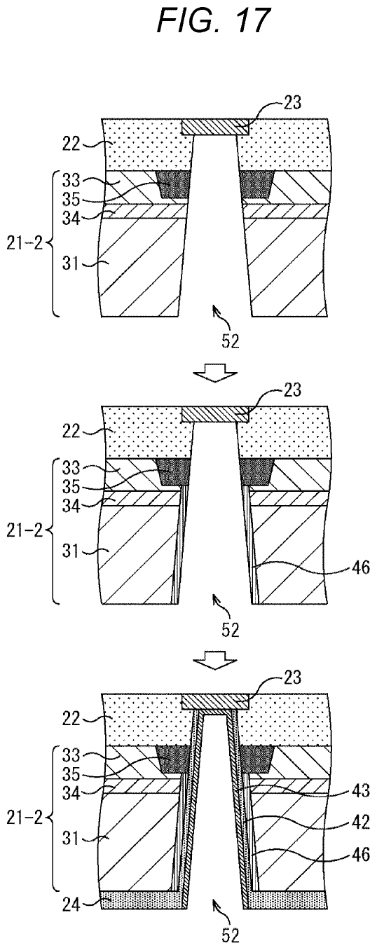

Steps of forming the through electrode 11-2 will be described with reference to FIG. 17.

First, as illustrated in a first part of FIG. 17, a TSV hole 52 penetrating the semiconductor layer 21-2 is formed so that the wire 23 opens through the element isolator 35 from the back surface side of the semiconductor layer 21-2.

Next, as illustrated in a second part of FIG. 17, the thermal oxide film 46 is formed on the inner side of the inner wall surface of the semiconductor layer 21-2 by performing a thermal oxidation treatment.

Then, as illustrated in a third part of FIG. 17, the insulating film 42 is formed so as to be stacked on the thermal oxide film 46, and the insulating film 24 is formed on the back surface of the semiconductor layer 21-2. Furthermore, the barrier metal 43 is formed so as to be stacked on the insulating film 42 and the wire 23.

Thereafter, the conductor 44 is embedded in the TSV hole 51 to form the through electrode 11-2 as illustrated in FIG. 16.

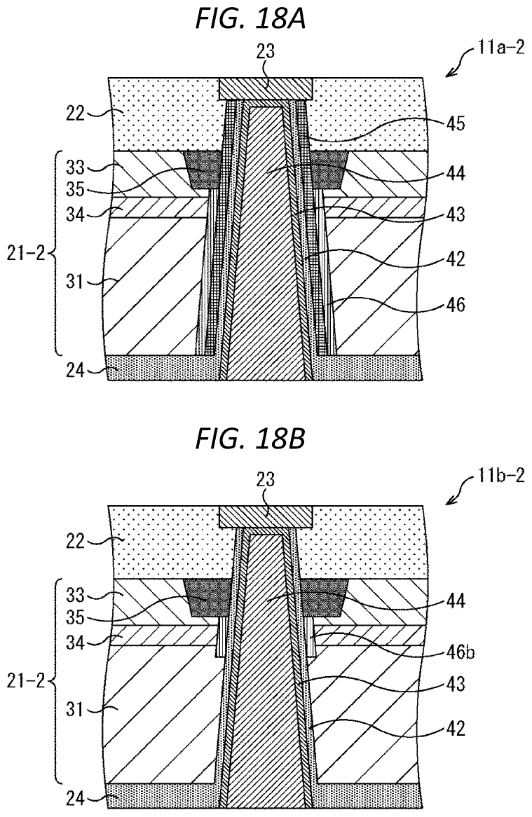

FIG. 18 is a diagram illustrating a modification of the through electrode 11-2.

A through electrode 11a-2 illustrated in A of FIG. 18 is formed by stacking an insulating film 45 of a type different from the insulating film 42 between the thermal oxide film 46 and the insulating film 42. That is, the through electrode 11a-2 has a configuration in which a two-layer film of the insulating film 42 and the insulating film 45 is formed. Of course, the through electrode 11-2 may adopt a configuration in which a multilayer film of two or more layers is formed.

The through electrode 11b-2 illustrated in B of FIG. 18 has such a length that covers at least the depletion layer 34, and has a configuration in which the thermal oxide film 46b is partially formed. That is, in order to reduce leakage in the depletion layer 34, the thermal oxide film 46b is only required to be formed so as to cover at least the depletion layer 34.

### <Configuration Example of Semiconductor Device>

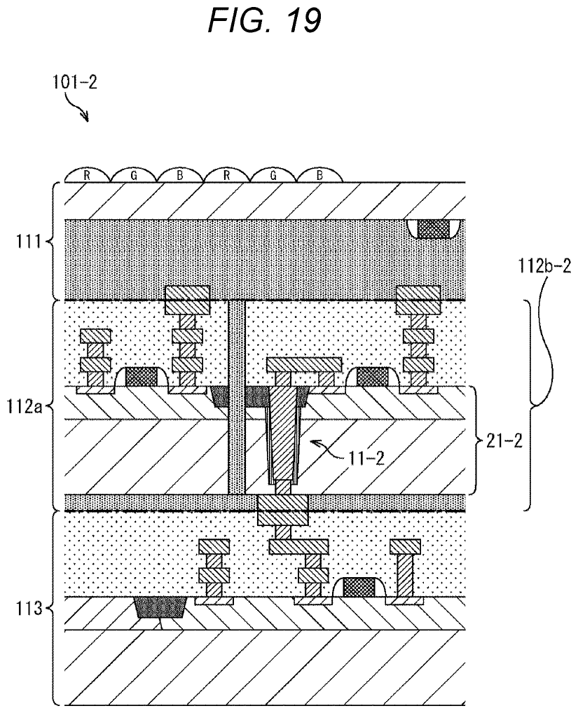

A semiconductor device using the through electrode 11-2 will be described with reference to FIGS. 19 to 27.

FIG. 19 is a sectional view illustrating a tenth configuration example of the semiconductor device.

FIG. 19 illustrates a semiconductor device 101-2 having a three-layer structure bonded at a bonding surface indicated by a one-dot chain line. The semiconductor device 101-2 has a three-layer structure in which a sensor chip 111 is disposed in a first layer, logic chips 112a and 112b-2 are disposed in a second layer, and a logic chip 113 is disposed in a third layer, and has a configuration called a multi-chip. For example, the sensor chip 111 includes an imaging element such as a CMOS image sensor, and the logic chips 112a and 112b-2 and the logic chip 113 include a signal processing circuit (logic circuit, memory, or the like) for performing signal processing on an image captured by the sensor chip 111.

Then, the semiconductor device 101-2 is configured such that the through electrode 11-2 is provided so as to penetrate the semiconductor layer 21-2 of the logic chip 112b-2. Therefore, the semiconductor device 101-2 can reduce leakage in the depletion layer 34 of the PN junction portion and shrink the keep out zone as described with reference to FIG. 16.

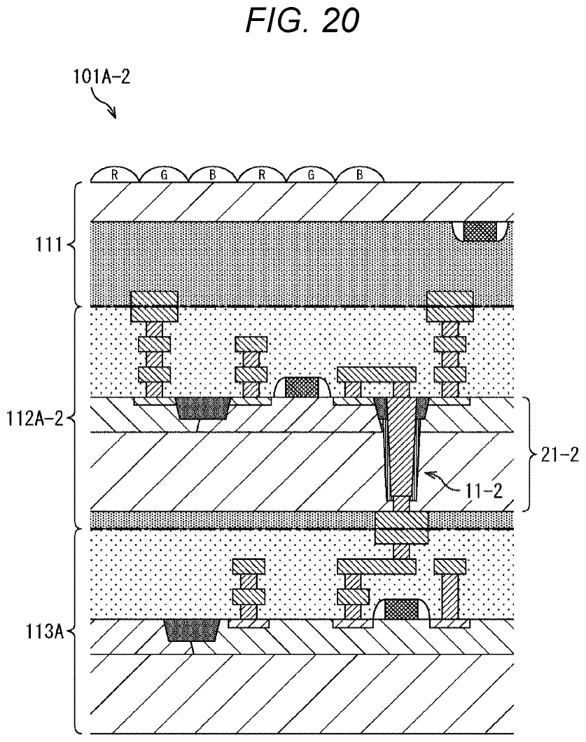

Note that, in each configuration example illustrated in FIGS. 20 to 27, the same reference sign is given to a configuration common to the configuration of the semiconductor device 101-2 in FIG. 19, and a detailed description thereof will not be repeated.

FIG. 20 is a sectional view illustrating an eleventh configuration example of the semiconductor device.

FIG. 20 illustrates a semiconductor device 101A-2 having a three-layer structure bonded at a bonding surface indicated by a one-dot chain line. The semiconductor device 101A-2 has a three-layer structure in which the sensor chip 111 is disposed in the first layer, a logic chip 112A-2 is disposed in the second layer, and a logic chip 113A is disposed in the third layer, and has a configuration called F2F in which a front surface side of the sensor chip 111 and a front surface side of the logic chip 112A-2 are bonded.

Then, the semiconductor device 101A-2 is configured such that the through electrode 11-2 is provided so as to penetrate the semiconductor layer 21-2 of the logic chip 112A-2. Therefore, the semiconductor device 101A-2 can reduce leakage in the depletion layer 34 of the PN junction portion and shrink the keep out zone as described with reference to FIG. 16.

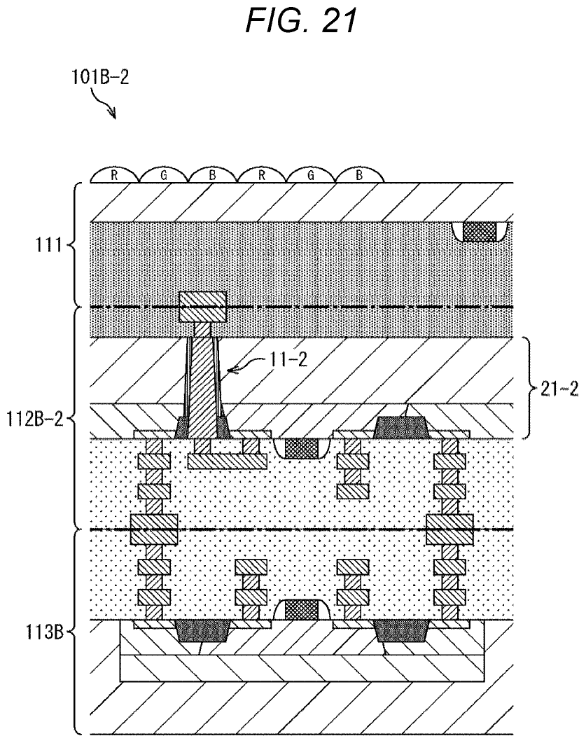

FIG. 21 is a sectional view illustrating a twelfth configuration example of the semiconductor device.

FIG. 21 illustrates a semiconductor device 101B-2 having a three-layer structure bonded at a bonding surface indicated by a one-dot chain line. The semiconductor device 101B-2 has a three-layer structure in which the sensor chip 111 is disposed in the first layer, a logic chip 112B-2 is disposed in the second layer, and a logic chip 113B is disposed in the third layer, and has a configuration called F2B in which a front surface side of the sensor chip 111 and a back surface side of the logic chip 112B-2 are bonded.

Then, the semiconductor device 101B-2 is configured such that the through electrode 11-2 is provided so as to penetrate the semiconductor layer 21-2 of the logic chip 112B-2. Therefore, the semiconductor device 101B-2 can reduce leakage in the depletion layer 34 of the PN junction portion and shrink the keep out zone as described with reference to FIG. 16.

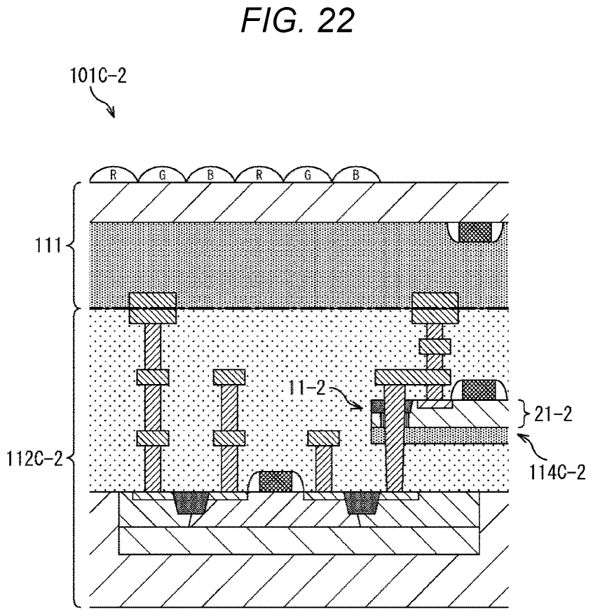

FIG. 22 is a sectional view illustrating a thirteenth configuration example of the semiconductor device.

FIG. 22 illustrates a semiconductor device 101C-2 having a two-layer structure bonded at a bonding surface indicated by a one-dot chain line. The semiconductor device 101C-2 has a two-layer structure in which the sensor chip 111 is disposed in the first layer and a logic chip 112C-2 is disposed in the second layer, and has a configuration called monolithic in which the logic chip 112C-2 is provided in a wiring layer of a logic chip 114C-2.

Then, the semiconductor device 101C-2 is configured such that the through electrode 11-2 is provided so as to penetrate the semiconductor layer 21-2 of the logic chip 114C-2. Therefore, the semiconductor device 101C-2 can reduce leakage in the depletion layer 34 of the PN junction portion and shrink the keep out zone as described with reference to FIG. 16.

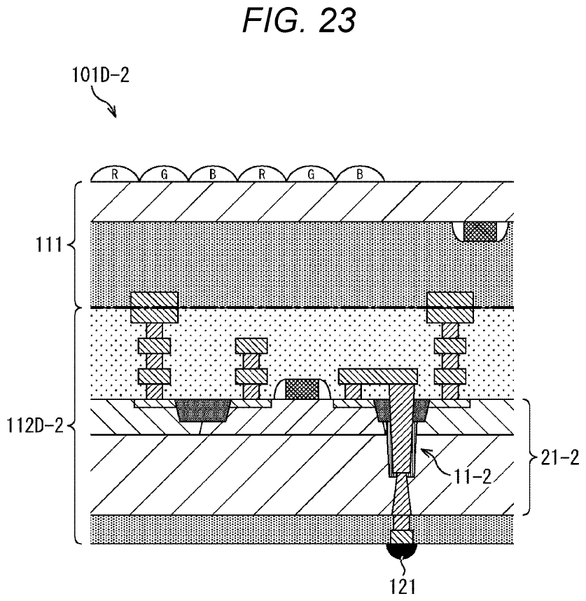

FIG. 23 is a sectional view illustrating a fourteenth configuration example of the semiconductor device.

FIG. 23 illustrates a semiconductor device 101D-2 having a two-layer structure bonded at a bonding surface indicated by a one-dot chain line. The semiconductor device 101D-2 has a two-layer structure in which the sensor chip 111 is disposed in the first layer and the logic chip 112D-2 is disposed in the second layer, and has a configuration called a back surface bump in which a bump 121 is provided on a back surface side of the logic chip 112D-2.

Then, the semiconductor device 101D-2 is configured such that the through electrode 11-2 is provided so as to be connected to the electrode connected to the bump 121 inside the semiconductor layer 21-2 of the logic chip 112D-2 and penetrate at least the depletion layer 34 of the PN junction portion illustrated in FIG. 16. Therefore, the semiconductor device 101D-2 can reduce leakage in the depletion layer 34 of the PN junction portion and shrink the keep out zone as described with reference to FIG. 16.

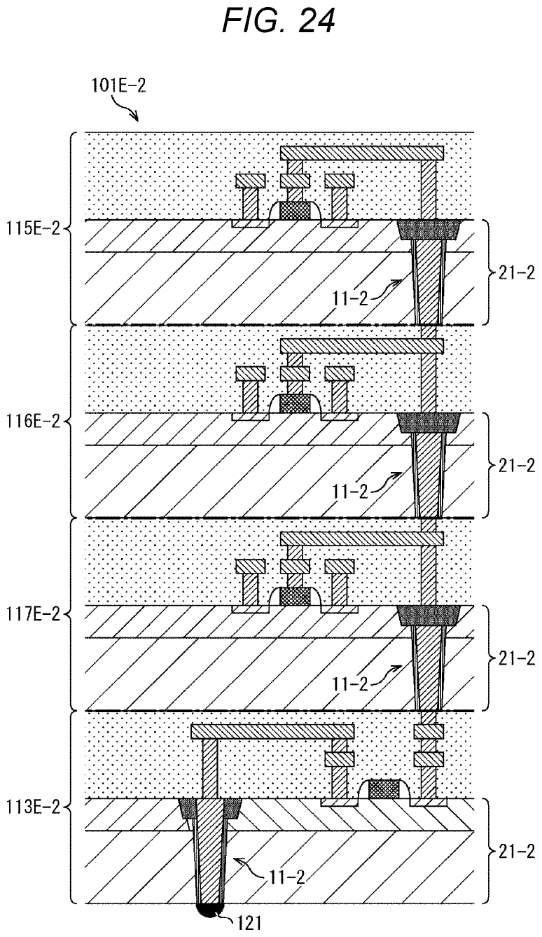

FIG. 24 is a sectional view illustrating a fifteenth configuration example of the semiconductor device.

FIG. 24 illustrates a semiconductor device 101E-2 having a four-layer structure bonded at a bonding surface indicated by a one-dot chain line. The semiconductor device 101E-2 has a four-layer structure in which a memory chip 115E-2 is disposed in a first layer, a memory chip 116E-2 is disposed in a second layer, a memory chip 117E-2 is disposed in a third layer, and a logic chip 113E-2 is disposed in a fourth layer, and has a configuration called a multistage memory/logic. Note that the semiconductor device 101E-2 can be mounted on a support substrate (not illustrated) with the bump 121 provided on a back surface side of the logic chip 113E-2 interposed therebetween. Of course, the semiconductor device 101E-2 may have a layered structure of four or more layers.

Then, the semiconductor device 101E-2 is configured such that the through electrode 11-2 is provided so as to penetrate the semiconductor layer 21-2 of the memory chip 115E-2, the through electrode 11-2 is provided so as to penetrate the semiconductor layer 21-2 of the memory chip 116E-2, the through electrode 11-2 is provided so as to penetrate the semiconductor layer 21-2 of the memory chip 117E-2, and the through electrode 11-2 is provided so as to penetrate the semiconductor layer 21-2 of the logic chip 113E-2 and be connected to the bump 121. Therefore, the semiconductor device 101E-2 can reduce leakage in the depletion layer 34 of the PN junction portion and shrink the keep out zone as described with reference to FIG. 16.

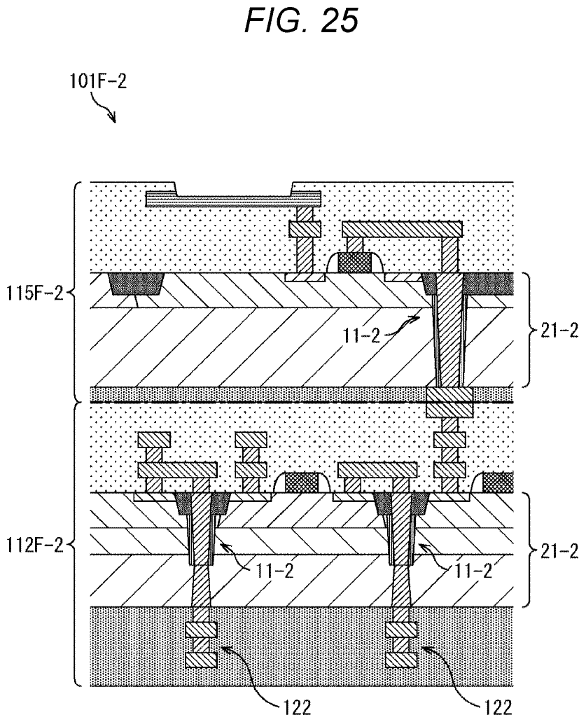

FIG. 25 is a sectional view illustrating a sixteenth configuration example of the semiconductor device.

FIG. 25 illustrates a semiconductor device 101F-2 having a two-layer structure bonded at a bonding surface indicated by a one-dot chain line. The semiconductor device 101F-2 has a two-layer structure in which the memory chip 115F-2 is disposed in the first layer and a logic chip 112F-2 is disposed in the second layer, and has a configuration in which the wire 122 for power supply is provided in a wiring layer of the logic chip 112F-2.

Then, the semiconductor device 101F-2 is configured such that the through electrode 11-2 is provided so as to penetrate the semiconductor layer 21-2 of the memory chip 115F-2. In addition, the semiconductor device 101F-2 is configured such that the through electrode 11-2 is provided so as to be connected to the electrode connected to the wire 122 inside the semiconductor layer 21-2 of the logic chip 112F-2 and penetrate at least the depletion layer 34 of the PN junction portion illustrated in FIG. 1. Therefore, the semiconductor device 101F-2 can reduce leakage in the depletion layer 34 of the PN junction portion and shrink the keep out zone as described with reference to FIG. 16.

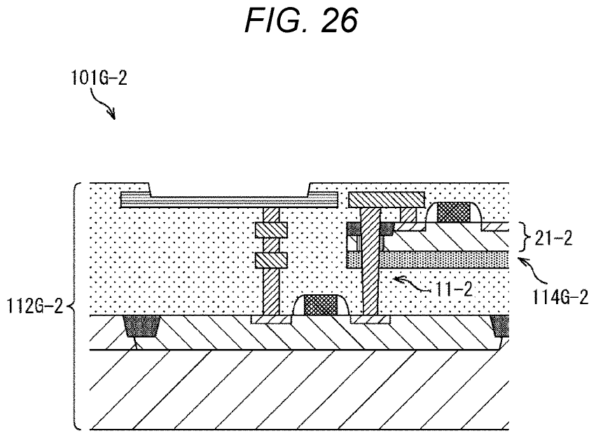

FIG. 26 is a sectional view illustrating a seventeenth configuration example of the semiconductor device.

FIG. 26 illustrates a semiconductor device 101G-2 having a single layer structure. The semiconductor device 101G-2 has a configuration called monolithic in which the logic chip 112G-2 is provided in a wiring layer of the logic chip 114G-2.

Then, the semiconductor device 101G-2 is configured such that the through electrode 11-2 is provided so as to penetrate the semiconductor layer 21-2 of the logic chip 114G-2. Therefore, the semiconductor device 101G-2 can reduce leakage in the depletion layer 34 of the PN junction portion and shrink the keep out zone as described with reference to FIG. 16.

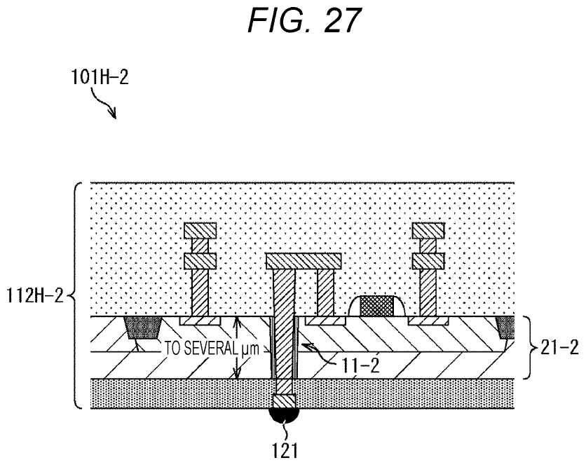

FIG. 27 is a sectional view illustrating an eighteenth configuration example of the semiconductor device.

FIG. 27 illustrates a semiconductor device 101H-2 having a single layer structure. The semiconductor device 101H-2 includes a logic chip 112H-2. Note that the semiconductor layer 21-2 of the logic chip 112H-2 has a thickness of several μm or less.

Then, the semiconductor device 101H-2 is configured such that the through electrode 11-2 is provided so as to penetrate the semiconductor layer 21-2 of the logic chip 112H-2, and the through electrode 11-2 is connected to the electrode connected to the bump 121. Therefore, the semiconductor device 101H-2 can reduce leakage in the depletion layer 34 of the PN junction portion and shrink the keep out zone as described with reference to FIG. 16.

As described above, the through electrode 11-2 to which the present technology is applied can be applied to imaging element chips such as the semiconductor devices 101-2 to 101D-2, a signal processing chip such as the semiconductor devices 101E-2 to 101H-2, and the like.

### <Method of Manufacturing Semiconductor Device>

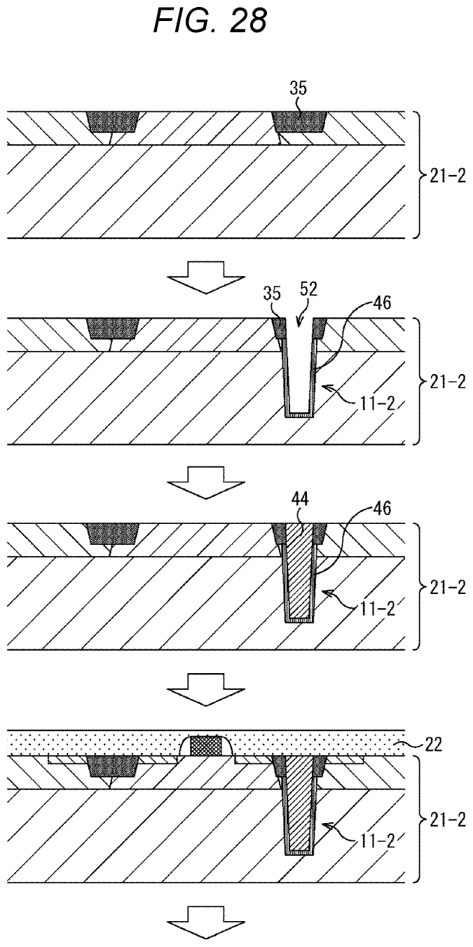

A method of manufacturing the semiconductor device 101A-2 in FIG. 20 will be described with reference to FIGS. 28 to 31.

In an eleventh step, as illustrated in a first part of FIG. 28, the semiconductor layer 21 having the front surface on which the element isolator 35 is formed is prepared by another process.

In a twelfth step, as illustrated in a second part of FIG. 28, the TSV hole 52 penetrating the element isolator 35 and dug to a predetermined depth of the semiconductor layer 21 is formed. Then, by performing the thermal oxidation treatment, the thermal oxide film 46 is formed on the inner side of the inner wall surface of the semiconductor layer 21-2 in the TSV hole 52.

In a thirteenth step, as illustrated in a third part of FIG. 28, the conductor 44 is embedded in the TSV hole 52 to form the through electrode 11-2. Note that, although not illustrated, the insulating film 42 and the barrier metal 43 are formed in the TSV hole 52 before the conductor 44 is embedded as described above with reference to FIG. 17. In addition, the back surface side of the semiconductor layer 21-2 is subjected to chemical mechanical polishing (CMP) to be thinned.

In a fourteenth step, as illustrated in a fourth part of FIG. 28, an element such as a transistor is formed on the front surface of the semiconductor layer 21, and an interlayer film to be the wiring layer 22 is stacked.

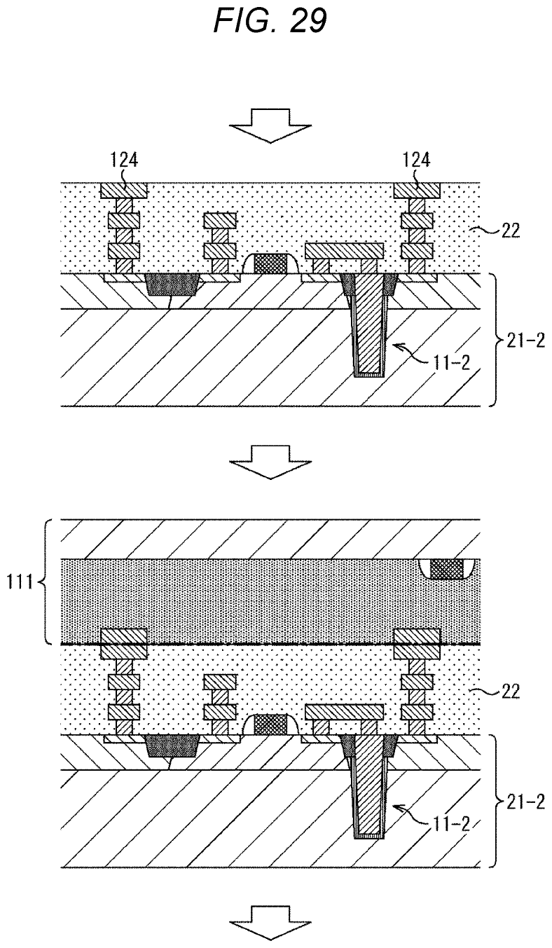

In a fifteenth step, as illustrated in an upper part of FIG. 29, multilayered wires are formed inside the wiring layer 22, and the Cu pad 124 is formed on the front surface of the wiring layer 22.

In a sixteenth step, as illustrated in a lower part of FIG. 29, the sensor chip 111 prepared by another process is stacked by Cu—Cu bonding.

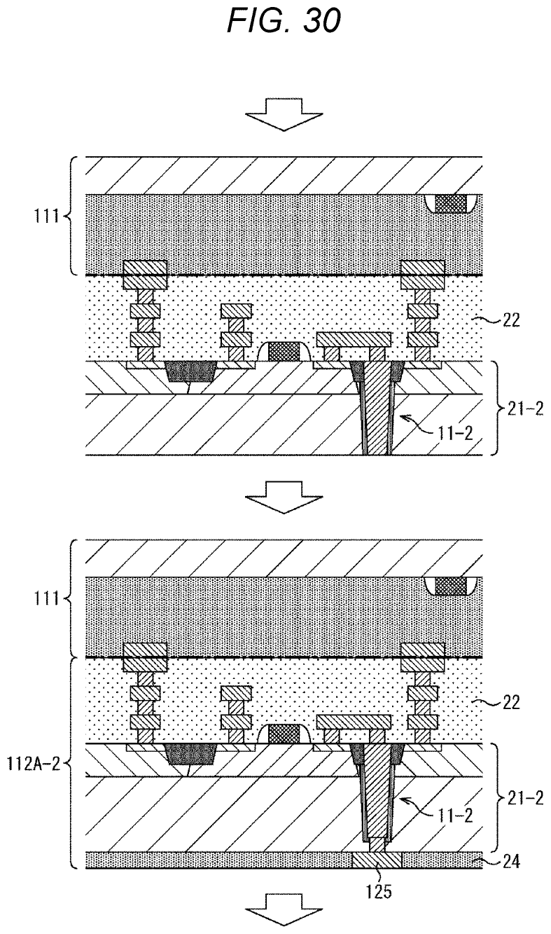

In a seventeenth step, as illustrated in an upper part of FIG. 30, the back surface side of the semiconductor layer 21-2 is subjected to CMP to be thinned until a tip of the through electrode 11-2 is exposed.

In an eighteenth step, as illustrated in a lower stage of FIG. 30, the insulating film 24 is formed on the back surface of the semiconductor layer 21-2, and a Cu pad 125 is embedded in a part of the insulating film 24 so as to be connected to the through electrode 11-2. In this manner, the logic chip 112A-2 is formed.

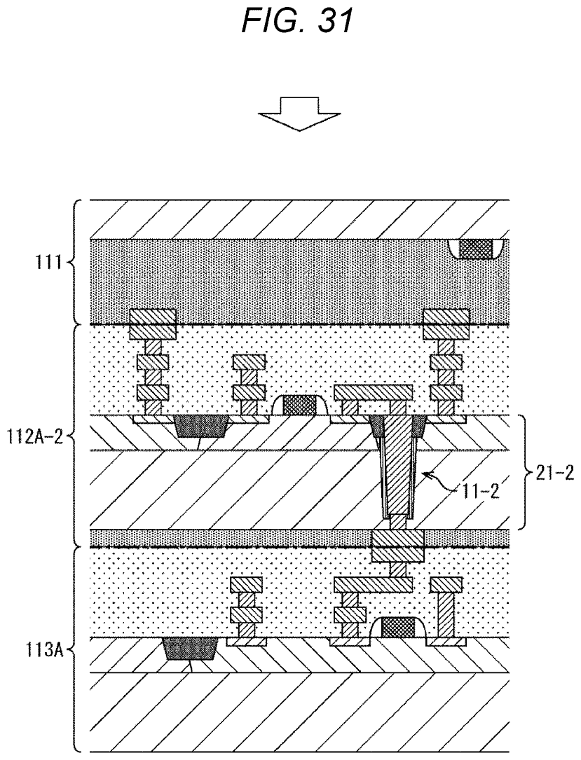

In a nineteenth step, as illustrated in FIG. 31, the logic chip 112A-2 and the logic chip 113A prepared by another process are Cu—Cu bonded and stacked. Thereafter, a color filter, an on-chip lens, or the like is formed on a back surface side of the sensor chip 111 to manufacture the semiconductor device 101A-2 as illustrated in FIG. 20.

The above steps makes it possible to manufacture the semiconductor device 101A-2 having a three-layer structure in which the sensor chip 111, the logic chip 112A-2, and the logic chip 113A are stacked, and the logic chip 112A-2 and the logic chip 113A are connected by using the through electrode 11-2.

Note that, in the present embodiment, the configuration in which the PN junction is provided by forming the N-well layer 33 on the P substrate 31 has been described, but the present technology may be applied to a configuration in which the PN junction is provided by forming a P-well layer on a substrate of N-type. That is, the PN junction is provided by forming a well with an impurity of a type different from the type of the substrate.

### <Configuration Example of Electronic Device>

The above-described semiconductor device 101 can be applied to various electronic devices such as an imaging system such as a digital still camera and a digital video camera, a mobile phone having an imaging function, or another device having an imaging function, for example.

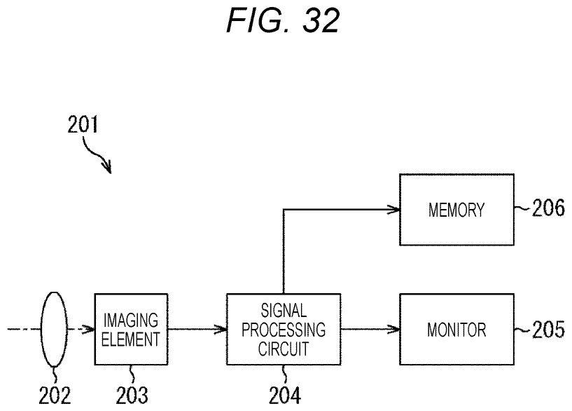

FIG. 32 is a block diagram illustrating a configuration example of an imaging device mounted on an electronic device.

As illustrated in FIG. 32, an imaging device 201 includes an optical system 202, an imaging element 203, a signal processing circuit 204, a monitor 205, and a memory 206, and can capture a still image and a moving image.

The optical system 202 including one or a plurality of lenses guides image light from an object (incident light) to the imaging element 203 to form an image on a light-receiving surface (sensor unit) of the imaging element 203.

As the imaging element 203, the above-described semiconductor device 101 is applied. Electrons are accumulated in the imaging element 203 for a certain period in accordance with the image formed on the light-receiving surface via the optical system 202. Then, a signal corresponding to the electrons accumulated in the imaging element 203 is supplied to the signal processing circuit 204.

The signal processing circuit 204 performs various types of signal processing on a pixel signal output from the imaging element 203. The image (image data) obtained by the signal processing applied by the signal processing circuit 204 is supplied to the monitor 205 to be displayed or supplied to the memory 206 to be stored (recorded).

By applying the semiconductor device 101 as described above, the imaging device 201 configured in this manner can further achieve, for example, higher functionality.

### <Use Example of Image Sensor>

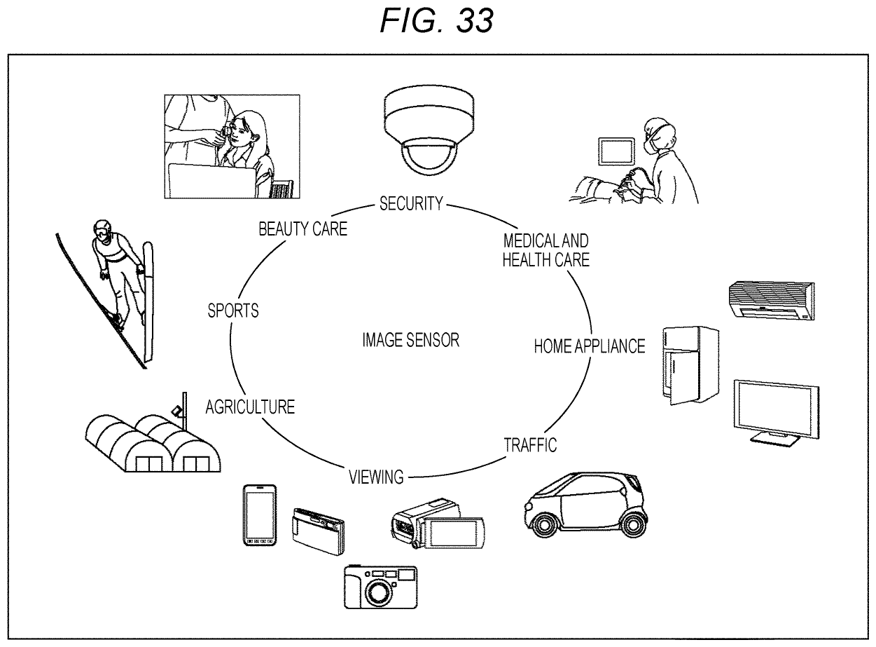

FIG. 33 is a diagram illustrating a use example of the above-mentioned image sensor (imaging element).

The image sensor described above can be used in various cases for sensing light such as visible light, infrared light, ultraviolet light, and X-ray as described below, for example.
A device that captures an image to be used for viewing, such as a digital camera and a portable device with a camera function.
A device for traffic purpose such as an in-vehicle sensor that captures images of the front, rear, surroundings, interior and the like of an automobile, a surveillance camera for monitoring traveling vehicles and roads, and a ranging sensor which measures a distance between vehicles and the like for safe driving such as automatic stop, recognition of a driver's condition and the like.
A device for home appliance such as a television, a refrigerator, and an air conditioner that images a user's gesture and performs device operation according to the gesture.
A device for medical and health care use such as an endoscope and a device that performs angiography by receiving infrared light.
A device for security use such as a security monitoring camera and an individual authentication camera.
A device used for beauty care, such as a skin measuring instrument for imaging skin, and a microscope for imaging the scalp.
A device used for sport, such as an action camera or a wearable camera for sports applications or the like.
A device used for agriculture, such as a camera for monitoring a condition of a field or crop.

### <Combination Examples of Configurations>

Note that the present technology can also have the following configurations.

(1)

A semiconductor device including
a first semiconductor chip,
a second semiconductor chip stacked on the first semiconductor chip and provided with a PN junction portion in a depth direction by forming an N-type well on a front surface of a substrate of P-type or forming a P-type well on a front surface of a substrate of N-type, and
a through electrode provided in a through hole penetrating the substrate, in which
the through electrode is configured such that a first insulating film having an insulating property for at least the PN junction portion is provided along an inner wall surface of the through hole.
   (2)

The semiconductor device according to (1) described above, in which
the first insulating film includes a ferroelectric film stacked on an outside of the front surface of the substrate on the inner wall surface of the through hole.
   (3)

The semiconductor device according to (2) described above, in which
the ferroelectric film includes a structure including a ferroelectric and having a negative or positive fixed charge.
   (4)

The semiconductor device according to (2) or (3) described above, in which
the ferroelectric film includes BaTiO3, Pb(Zr, Ti)O3, BiFeO3, SrBi2Ta2O9, (Bi, La)4Ti3O12, or a High-k ferroelectric.
   (5)

The semiconductor device according to any of (2) to (4) described above, in which
the ferroelectric film is provided with a length covering at least a depletion layer of the PN junction portion.
   (6)

The semiconductor device according to any of (2) to (5) described above, in which
the ferroelectric film is formed by a single layer or a plurality of layers.
   (7)

The semiconductor device according to any of (2) to (6) described above, in which
the through electrode is stacked on the ferroelectric film and includes a second insulating film containing at least oxygen.
   (8)

The semiconductor device according to any of (1) to (7) described above, in which
at least one end of the through electrode is connected to a wire constituting a part of an internal circuit provided in the second semiconductor chip.
   (9)

The semiconductor device according to (1) described above, in which
the first insulating film includes a thermal oxide film provided inside the front surface of the substrate on the inner wall surface of the through hole and formed by thermal oxidation treatment on the substrate.
   (10)

The semiconductor device according to (9) described above, in which
the thermal oxide film is formed by changing silicon on the front surface of the substrate into a silicon oxide film by oxidation by heating in the thermal oxidation treatment.
   (11)

The semiconductor device according to (9) or (10) described above, in which
the thermal oxide film is formed only in a portion of the substrate in the through hole.
   (12)

The semiconductor device according to any of (9) to (11) described above, in which
the through hole penetrates an element isolator provided on the front surface of the substrate, and
the thermal oxide film is provided at a position deeper than the element isolator.
   (13)

The semiconductor device according to any of (9) to (12) described above, in which
the thermal oxide film is provided with a length covering at least a depletion layer of the PN junction portion.
   (14)

The semiconductor device according to any of (9) to (13) described above, in which
the through electrode is stacked on the thermal oxide film and includes a second insulating film containing at least oxygen.
   (15)

The semiconductor device according to any of (1) to (14) described above, in which
the first semiconductor chip includes an image sensor, and
the second semiconductor chip is provided with a signal processing circuit that performs signal processing on an image captured by the image sensor.
   (16)

The semiconductor device according to any of (1) to (15) described above, in which
the first semiconductor chip and the second semiconductor chip are provided with a signal processing circuit including a logic circuit and a memory.
   (17)

The semiconductor device according to any of (1) to (16) described above, in which
at least one or more layers of other semiconductor chips are further stacked on the second semiconductor chip.
   (18)

An electronic device including a semiconductor device including
a first semiconductor chip,
a second semiconductor chip stacked on the first semiconductor chip and provided with a PN junction portion in a depth direction by forming an N-type well on a front surface of a substrate of P-type or forming a P-type well on a front surface of a substrate of N-type, and
a through electrode provided in a through hole penetrating the substrate, in which
the through electrode is configured such that a first insulating film having an insulating property for at least the PN junction portion is provided along an inner wall surface of the through hole.
   (19)

A method of manufacturing a semiconductor device including
forming a through hole penetrating a substrate of a second semiconductor chip stacked on a first semiconductor chip and provided with a PN junction portion in a depth direction by forming an N-type well on a front surface of the P-type substrate or forming a P-type well on a front surface of the N-type substrate, and
forming a through electrode having a configuration in which a first insulating film having an insulating property for at least the PN junction portion is provided along an inner wall surface of the through hole.

Note that, the present embodiment is not limited to the embodiment described above, and various modifications can be made without departing from the gist of the present disclosure. Furthermore, the effects described in the present specification are merely examples and are not limited, and other effects may be provided.

### REFERENCE SIGNS LIST

11 Through electrode
21 Semiconductor layer
22 Wiring layer
23 Wire
24 Insulating film
31 P substrate
32 Deep N-well layer
33 N-well layer
34 Depletion layer
35 Element isolator
41 Ferroelectric film
42 Insulating film
43 Barrier metal
44 Conductor
45 Insulating film
46 Thermal oxide film
101 Semiconductor device
111 Sensor chip
112 to 114 Logic chip
115 to 117 Memory chip
121 Bump
122 Wire
123 to 125 Cu pad

What is claimed is:

1. A semiconductor device comprising:
a first semiconductor chip;
a second semiconductor chip stacked on the first semiconductor chip and provided with a PN junction portion in a depth direction by forming an N-type well on a front surface of a substrate of P-type or forming a P-type well on a front surface of a substrate of N-type; and
a through electrode provided in a through hole penetrating the substrate, wherein
the through electrode is configured such that a first insulating film having an insulating property for at least the PN junction portion is provided along an inner wall surface of the through hole.

2. The semiconductor device according to claim 1, wherein
the first insulating film includes a ferroelectric film stacked on an outside of the front surface of the substrate on the inner wall surface of the through hole.

3. The semiconductor device according to claim 2, wherein
the ferroelectric film includes a structure including a ferroelectric and having a negative or positive fixed charge.

4. The semiconductor device according to claim 2, wherein
the ferroelectric film includes BaTiO3, Pb(Zr, Ti)O3, BiFeO3, SrBi2Ta2O9, (Bi, La)4Ti3O12, or a High-k ferroelectric.

5. The semiconductor device according to claim 2, wherein
the ferroelectric film is provided with a length covering at least a depletion layer of the PN junction portion.

6. The semiconductor device according to claim 2, wherein
the ferroelectric film is formed by a single layer or a plurality of layers.

7. The semiconductor device according to claim 2, wherein
the through electrode is stacked on the ferroelectric film and includes a second insulating film containing at least oxygen.

8. The semiconductor device according to claim 1, wherein
at least one end of the through electrode is connected to a wire constituting a part of an internal circuit provided in the second semiconductor chip.

9. The semiconductor device according to claim 1, wherein
the first insulating film includes a thermal oxide film provided inside the front surface of the substrate on the inner wall surface of the through hole and formed by thermal oxidation treatment on the substrate.

10. The semiconductor device according to claim 9, wherein
the thermal oxide film is formed by changing silicon on the front surface of the substrate into a silicon oxide film by oxidation by heating in the thermal oxidation treatment.

11. The semiconductor device according to claim 9, wherein
the thermal oxide film is formed only in a portion of the substrate in the through hole.

12. The semiconductor device according to claim 9, wherein
the through hole penetrates an element isolator provided on the front surface of the substrate, and
the thermal oxide film is provided at a position deeper than the element isolator.

13. The semiconductor device according to claim 9, wherein
the thermal oxide film is provided with a length covering at least a depletion layer of the PN junction portion.

14. The semiconductor device according to claim 9, wherein
the through electrode is stacked on the thermal oxide film and includes a second insulating film containing at least oxygen.

15. The semiconductor device according to claim 1, wherein
the first semiconductor chip includes an image sensor, and
the second semiconductor chip is provided with a signal processing circuit that performs signal processing on an image captured by the image sensor.

16. The semiconductor device according to claim 1, wherein
the first semiconductor chip and the second semiconductor chip are provided with a signal processing circuit including a logic circuit and a memory.

17. The semiconductor device according to claim 1, wherein
at least one or more layers of other semiconductor chips are further stacked on the second semiconductor chip.

18. An electronic device comprising a semiconductor device including
a first semiconductor chip,
a second semiconductor chip stacked on the first semiconductor chip and provided with a PN junction portion in a depth direction by forming an N-type well on a front surface of a substrate of P-type or forming a P-type well on a front surface of a substrate of N-type, and
a through electrode provided in a through hole penetrating the substrate, wherein
the through electrode is configured such that a first insulating film having an insulating property for at least the PN junction portion is provided along an inner wall surface of the through hole.

19. A method of manufacturing a semiconductor device, the method comprising:
forming a through hole penetrating a substrate of a second semiconductor chip stacked on a first semiconductor chip and provided with a PN junction portion in a depth direction by forming an N-type well on a front surface of the P-type substrate or forming a P-type well on a front surface of the N-type substrate; and
forming a through electrode having a configuration in which a first insulating film having an insulating property for at least the PN junction portion is provided along an inner wall surface of the through hole.
